(19) United States
(12) Patent Application Publication
(10) Pub. No.: US 2024/0112056 A1
(43) Pub. Date: Apr. 4, 2024

(54) ANTI-FUSE AND FUSE STRUCTURES USING ANISOTROPIC ETCHING OF THE SUBSTRATE USING A PATTERN OF ETCH RELEASE HOLES FOR IMPROVING THE FUNCTIONALITY OF QUBIT CIRCUITS

(71) Applicant: INTERNATIONAL BUSINESS MACHINES CORPORATION, ARMONK, NY (US)

(72) Inventors: Vivekananda P. Adiga, Ossining, NY (US); Russell A. Budd, North Salem, NY (US); Charles Thomas Rettner, San Jose, CA (US); Stephen M. Gates, New York, NY (US)

(21) Appl. No.: 17/936,843

(22) Filed: Sep. 29, 2022

(51) Int. Cl. G06N 10/40; H01L 21/822; H01L 23/525; H03K 17/92

(52) U.S. Cl. CPC G06N 10/40; H01L 21/822; H01L 23/5258; H03K 17/92

(57) ABSTRACT

A method of constructing a superconducting switch includes providing a substrate. A first superconducting metal line is fabricated on the substrate, wherein the superconducting metal line has a left portion, a right portion, and a center portion patterned along a first crystalline direction of the substrate. One or more etch release holes are provided in the center portion of the first superconducting metal line. The center portion of the superconducting metal line is released from the substrate with an anisotropic etch through the etch release holes in a manner that reduces the undercut distance elsewhere on the substrate

### BACKGROUND

### Technical Field

The present disclosure generally relates to quantum circuits, and more particularly, to superconducting connectors that can be used to program quantum circuits.

### Description of the Related Art

Superconducting quantum computing is an implementation of a quantum computer in superconducting electronic circuits. Quantum computation studies the application of quantum phenomena for information processing and communication. Various models of quantum computation exist, and the most popular models include the concepts of qubits and quantum gates. A qubit is a generalization of a bit that has two possible states, but can be in a quantum superposition of both states. A quantum gate is a generalization of a logic gate, however the quantum gate describes the transformation that one or more qubits will experience after the gate is applied on them, given their initial state. Various quantum phenomena, such as superposition and entanglement, do not have analogs in the world of classical computing and therefore may involve special structures, techniques, and materials. Further, qubit technology is still at its infancy and developing components, such as a qubit having a predetermined frequency with high precision, is a challenge. For example, qubit frequencies can be tuned using coils or by modifying junction resistances using laser or changing the capacitances by either etching into substrate. Each one of these approaches poses its own challenge.

### SUMMARY

According to one embodiment, a method of constructing a superconducting switch, includes providing a substrate. A first superconducting metal line is fabricated over the substrate. The superconducting metal line has a lateral first portion, a lateral second portion, and a lateral center portion. Center portion is patterned along a first crystalline direction of the substrate. One or more etch release holes are provided in the center portion of the first superconducting metal line. The center portion of the superconducting metal line is released from the substrate with an anisotropic etch through the etch release holes. In this way, an undercut of the substrate can be limited to a distance comparable to the etch release holes, rather than the width of the line. The same wafer can be used for further processing and development of additional semiconductor structures thereon, including additional anti-fuses, and transistor structures.

In one embodiment, the first crystalline direction of the substrate is 100.

In one embodiment, the anisotropic etch through the etch release holes is 300 nm or less.

In one embodiment, the anisotropic etch is by way of wet etch using at least one of Potassium Hydroxide (KOH), all quaternary hydroxides like tetramethyl ammonium hydroxide (TMAH), or tetraethyl ammonium hydroxide (TEAH).

In one embodiment, a compressive stress on the first superconducting metal line is provided during the deposition of the first superconducting metal line, causing the released portion of the superconducting metal line to buckle away from the substrate.

In one embodiment, a bimorph structure is created in the center portion of the first superconducting metal line, causing the released portion of the superconducting metal line to buckle away from the substrate. The bimorph structure is created by placing a second material directly on top or directly below the center portion of the superconducting metal line. The second material may have a coefficient of expansion that is different from that of the first superconducting metal line.

In one embodiment, the method further includes removing the second material upon buckling of the center portion of the first superconducting metal line.

In one embodiment, the etch release holes are rectangular and arranged with an offset between rows of release holes.

In one embodiment, the etch release holes are non-uniform in geometry.

In one embodiment, the buckled center portion of the first superconducting metal line is a fuse that is configured to receive an output of a laser.

In one embodiment, the buckled center portion of the first superconducting metal line is an anti-fuse that is configured to receive an output of a laser. Advantageously, a fuse can be provided on same metal plane of the first superconducting metal line.

In one embodiment, the fuse is aligned along a 100 crystalline direction of silicon substrate, and the anti-fuse is aligned along a 110 crystalline direction of the substrate.

In one embodiment, the substrate comprises silicon (Si). Etching a portion of the substrate includes using at least one of tetramethyl ammonium hydroxide (TMAH), potassium hydroxide (KOH), or tetraethyl ammonium hydroxide (TEAH).

According to one embodiment, a fuse structure includes a substrate. There is a first superconducting metal line on top of the substrate. The superconducting metal line has a lateral first portion, a second lateral portion, and a lateral center portion between the lateral first and second portions, patterned along a first crystalline direction of the substrate. One or more etch release holes are in the center portion of the first superconducting metal line. The center portion of the superconducting metal line has a gap from the substrate based on the etch release holes.

In one embodiment, the first crystalline direction of the substrate is 100.

In one embodiment, the first superconducting metal line includes a compressive stress configured to buckle the center portion of the first superconducting metal line away from the substrate.

In one embodiment, a second material is on top or directly below the center portion of the first superconducting metal line creating a bimorph structure that facilitates buckling of the released portion of the superconducting metal line away from the substrate upon release. The second material has a coefficient of expansion that is different from that of the first superconducting metal line.

In one embodiment, the center portion of the superconducting metal line has a gap between the center portion and the substrate that is sufficient to receive an output power of a laser to create an electrical open between the lateral first portion and the lateral second portion of the superconducting metal line.

In one embodiment, the center portion of the superconducting metal line has a gap between the center portion and the substrate that is sufficient to receive an output power of a laser to create an electrical short between the lateral first portion and the lateral second portion of the superconducting metal line.

In one embodiment, the etch release holes are rectangular and arranged interstitially between rows of release holes.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments.

Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 is an example superconducting switch system, consistent with an illustrative embodiment.

FIG. 2 illustrates a top view and a side view of a superconducting switch device that includes a shallow anisotropic etch that uses the substrate as a sacrificial material, consistent with an illustrative embodiment.

FIG. 3 is a process that relates to orchestration of the creation of superconducting switch device that includes a shallow anisotropic etch that uses the substrate as a sacrificial material, similar to that discussed in the context of FIG. 2.

FIG. 4 is a functional block diagram illustration of a computer hardware platform that can be used to control various aspects of a suitable computing environment in which the various embodiments of the features discussed herein can be implemented.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the direction of the Figures being described. Since components of embodiments of the disclosure can be positioned in a number of different directions, the directional terminology is used for purposes of illustration and is in no way limiting. Thus, it will be understood that the spatially relative terminology is intended to encompass different directions of the device in use or operation in addition to the direction depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other directions) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope. It should be appreciated that the figures and/or drawings accompanying this disclosure are exemplary, non-limiting, and not necessarily drawn to scale.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

As used herein, certain terms are used indicating what may be considered an idealized behavior, such as, for example, “lossless,” “superconductor,” or “superconducting,” which are intended to cover functionality that may not be exactly ideal but is within acceptable margins for a given application. For example, a certain level of loss or tolerance may be acceptable such that the resulting materials and structures may still be referred to by these “idealized” terms.

The concepts herein can relate to superconducting circuits, such as those used in quantum technology and quantum chips. Regarding quantum technology, the electromagnetic energy associated with a qubit can be stored, for example, in so-called Josephson junctions and in the capacitive and inductive elements that are used to form the qubit. In other examples, there may be spin qubits coupled to resonators or topological qubits, microfabricated ion traps, etc. Other types of superconducting components are supported by the teachings herein as well, including (without limitation), circulators, isolators, amplifiers, filters, active control electronics such as rapid single flux quantum (RSFQ), etc., that can be programmed (e.g., finetuned by way of turning ON and OFF switch devices, sometimes referred to herein as fuses or anti-fuses). Accordingly, various components described herein can be programmed and/or reprogrammed by such fuses and/or anti-fuses. As used herein, a “superconducting fuse device” (sometimes also referred to herein as a “fuse”) can comprise a type of superconducting switch device that can provide an electrical connection that can be opened (e.g., to interrupt the flow of electrical current between two electrodes). A “superconducting anti-fuse device” (sometimes also referred to herein simply as an “anti-fuse”) can comprise another type of superconducting switch device that can be closed to provide an electrical connection (e.g., to enable electrical current to flow between two electrodes). Fuses and anti-fuses are collectively referred to herein as superconducting switch devices.

A qubit system may include one or more readout resonators coupled to the qubit. A readout resonator may be a transmission line that includes a capacitive connection to ground on one side and is either shorted to the ground on the other side, such as for a quarter wavelength resonator, or may have a capacitive connection to ground, such as for a half wavelength resonator, which results in oscillations within the transmission line, with the resonant frequency of the oscillations being close to the frequency of the qubit. For example, the readout resonator affects a pulse coming from the control/measurement instruments at the readout resonator frequency. The pulse acts as a measurement that decoheres the qubit and makes it collapse into a state of “one” or “zero,” thereby imparting a phase shift on that measurement pulse.

Between qubits there may be a coupling resonator, which allows coupling different qubits together in order to realize quantum logic gates. The coupling resonator is typically structurally similar to the readout resonator in that it is a transmission line that includes capacitive connections to ground on both sides, which also results in oscillations within the coupling resonator. When a qubit is implemented as a transmon, each side of the coupling resonator is coupled (e.g., capacitively or inductively) to a corresponding qubit by being in adequate proximity to (e.g., in an effective capacitive coupling distance of) the qubit. Since each side of the coupling resonator has coupling with a respective different qubit, the two qubits are coupled together through the coupling resonator. In this way, there is mutual interdependence in the state between coupled qubits, thereby allowing a coupling resonator to use the state of one qubit to control the state of another qubit. Entanglement occurs when the interaction between two qubits is such that the states of the two cannot be specified independently but can only be specified for the whole system. In this way, the states of two qubits are linked together such that a measurement of one of the qubits, causes the state of the other qubit to alter. The structures discussed herein can provide redundancy to quantum circuit, where qubits that are to be part of processor and those that are not can be selected.

In one aspect, the teachings herein relate to superconducting switch devices that provide a technical improvement (e.g., benefit) of a programmable and/or a reprogrammable quantum circuit, where based on one or more criteria of a quantum circuit, such as coherence, fidelity, frequency collisions/crowding, efficiency, lattice geometries that enable quantum error correction (i.e., with surface codes) and/or another performance criterion, the connectivity (e.g., coupling) of one or more quantum computing elements can be configured and/or reconfigured. For example, a use could be to disconnect (e.g., via a fuse) certain malfunctioning (e.g., having poor coherence, fidelity, etc.) portions of the circuits and connecting (e.g., anti-fuse) better performing portions of the circuit to enable efficient operation of a quantum processor. Accordingly, by virtue of the teachings herein, a quantum processor can provide a programmable and/or reprogrammable quantum circuit that can be modified to improve one or more performance criteria of such a quantum circuit and/or provide redundancy (e.g., replacement of malfunctioning components). Such one or more embodiments of the subject disclosure can thereby improve one or more performance criteria (e.g., coherence, accuracy, fidelity, and/or another performance criterion) of such a quantum processor comprising one or more of the various embodiments of the subject disclosure.

In some embodiments, the teachings herein use a substrate as a sacrificial material by undercutting it with a suitable technique, such as wet etching or reactive ion etching, thereby reducing fabrication steps. The directionality of this etch provides the technical benefit of being able to use a same process to provide superconducting fuse and anti-fuse structures with a same fabrication step (e.g., such as Ethylenediamine pyrocatechol (EDP), Hydrazine, Potassium Hydroxide (KOH), all quaternary hydroxides like tetramethyl ammonium hydroxide (TMAH), tetraethyl ammonium hydroxide (TEAH) etc.) These act as oxidants. Note that, these individual solutions can be mixture of different additives, such as isopropyl alcohol, pyro-catechol which act as complexing agents, and sometimes surfactants that control the etch characteristics of different silicon planes are added to the mixture. Etch release holes are formed on a center portion of superconducting metal line that is on top of a substrate. The etch release holes allow the etchants to etch just a thin layer of the substrate in the center portion below the center portion of the superconducting metal line, thereby minimizing etching and undercut of other areas of the substrate. The etching of the substrate under the superconducting metal line releases it from the substrate facilitating the buckling of the center portion of the superconducting metal line away from the etched substrate. In this way, a bridge structure is created that has a sufficient gap between the fuse (or anti-fuse) and the substrate.

In one aspect, these superconducting switch devices provide bidirectional and/or incremental frequency tuning capability by adding and/or removing circuit elements, such as capacitors and/or inductors in the quantum circuits, as well as providing redundancy, thereby enhancing the reliability of a quantum system. The superconducting switch devices simplify the fabrication process while not adversely impacting qubit coherence. The techniques described herein may be implemented in a number of ways. Example implementations are provided below with reference to the following figures.

### Example Superconducting Switch System

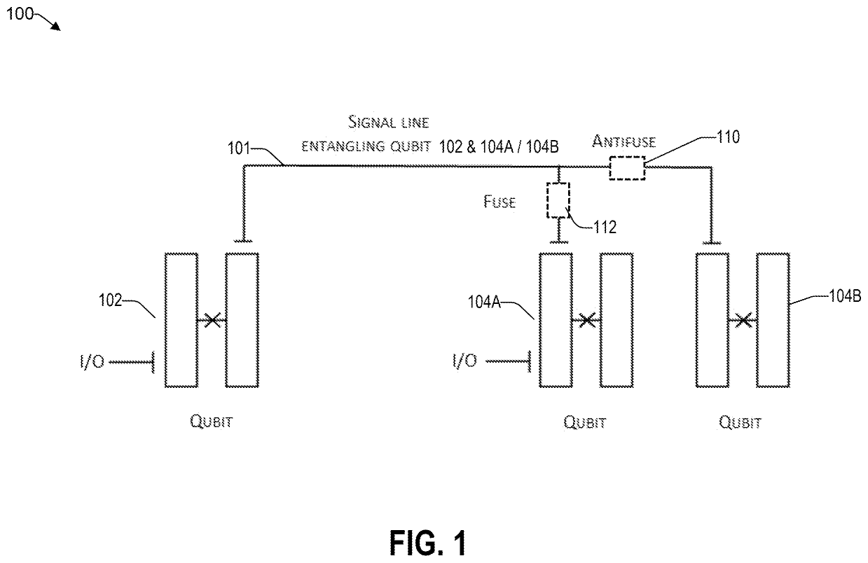

Reference now is made to FIG. 1, which is an example superconducting switch system 100, consistent with an illustrative embodiment. In the example of FIG. 1, one or more superconducting switch devices, represented by anti-fuse 110 and fuse 112 can be used to alter the entangling state (e.g., connected and disconnected) between quantum computing elements, represented by qubits 102, 104A, and 104B using the signal line 101. By way of example, consider a fabrication defect rendering qubit 104A defective. The signal line 101 can be reprogrammed to alter the entangling between qubit 102 and qubits 104A and 104B. For example, the signal line 101 can be severed between qubit 102 and qubit 104 by programming (e.g., blowing) fuse 112. The signal line 101 can be connected to qubit 104B instead by programming (e.g., shorting) anti-fuse 110, thereby entangling qubit 102 with previously redundant qubit 104B. In this way, an example programmable quantum circuit is provided. In one embodiment, the anti-fuse 110 and the fuse 112 are fabricated on a common layer, which substantially reduces complexity and manufacturing cost. The fabrication of the subject fuses and anti-fuses is discussed in more detail later.

### Example Fuse and Anti-Fuse Structures and Fabrication Thereof

The teachings herein provide various superconducting switch devices that may be implemented as fuses and/or anti-fuses. These superconducting switch devices can be used, for example, to alter the coupling of a first quantum computing element and as second quantum computing element that is coupled to the electrodes of a superconducting switch device. The fabrication of the superconducting switch devices discussed herein can comprise multi-step sequences of, for example, photolithographic and/or chemical processing steps that facilitate creation of electronic-based systems, devices, components, and/or circuits in a semiconducting and/or a superconducting device (e.g., an integrated circuit). For instance, a superconducting switch device can be fabricated on one or more substrates. In various embodiments, the substrate, may comprise any suitable material or combination of materials, such as doped or undoped silicon, glass, dielectrics, etc. For example, the substrate may comprise a semiconductor-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating films on top. In another embodiment, the substrate comprises intrinsic (i.e., undoped) silicon (Si). Other materials that may be used for the substrate include, without limitation, sapphire, aluminum oxide, germanium, gallium arsenide (GaAs) or any of the other III-V periodic table compounds, indium phosphide (InP), silicon carbide (SiC), a superconducting alloy of silicon and germanium, quartz, etc. Thus, as used herein, the term substrate 206 refers to a foundation upon which various superconducting structures can be built.

The superconducting fuse or anti-fuse structures discussed herein can be fabricated by using various techniques including, but not limited to: photolithography, microlithography, nanolithography, nanoimprint lithography, photomasking techniques, patterning techniques, photoresist techniques (e.g., positive-tone photoresist, negative-tone photoresist, hybrid-tone photoresist, and/or another photoresist technique), etching techniques (e.g., reactive ion etching (RIE), dry etching, wet etching, ion beam etching, plasma etching, laser ablation, and/or another etching technique), evaporation techniques, sputtering techniques, plasma ashing techniques, thermal treatments (e.g., rapid thermal anneal, furnace anneals, thermal oxidation, and/or another thermal treatment), chemical vapor deposition (CVD), atomic layer deposition (ALD), physical vapor deposition (PVD), molecular beam epitaxy (MBE), electrochemical deposition (ECD), chemical-mechanical planarization (CMP), back-grinding techniques, and/or another technique for fabricating an integrated circuit.

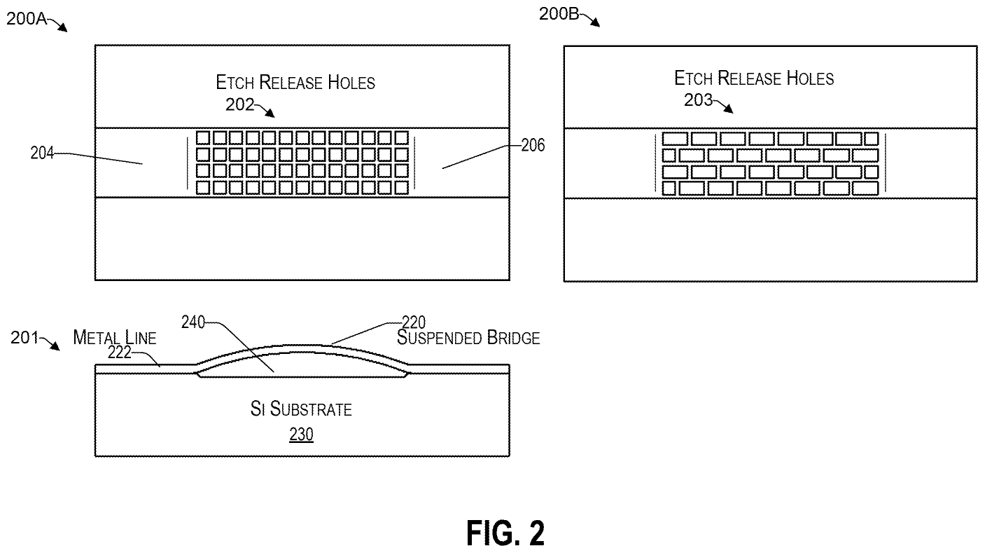

FIG. 2 illustrates a top view 200A, 200B, and a side view 201 of a superconducting switch device that includes a shallow anisotropic etch that uses a portion of the substrate as a sacrificial material, consistent with an illustrative embodiment. In various embodiments, the superconducting switch device may be a fuse or an anti-fuse. There is a substrate 230, which may comprise silicon (Si). In one embodiment, the substrate is etched in a first crystalline direction of the substrate (e.g., 100 in Si). A shallow (300 nm or less) anisotropic etch (e.g., wet preferred) can be performed in the first crystalline direction (e.g., 100) of the substrate 230. An underlying region of the substrate below the suspended portion of the bridge 220 is removed by a wet etching process using at least one of Potassium Hydroxide (KOH), all quaternary hydroxides like tetramethyl ammonium hydroxide (TMAH), tetraethyl ammonium hydroxide (TEAH), etc.

There is a superconducting metal line 222, sometimes referred to as a superconducting metal layer, on top of the substrate 230, wherein a portion of the metal line 220 is suspended over the substrate 230, thereby forming a bridge between the left portion 204 and the right portion 206 of the metal line 222. In various embodiments, the superconducting material of the bridge may comprise niobium, aluminum, and/or any other suitable superconducting material, which can be deposited via any suitable patterning and/or lithographic technique. For example, the clearance 240 can be created by popping (e.g., buckling the suspended bridge 220 in the center portion the stressed bridge 220 away from the substrate 230), discussed in more detail below. In one embodiment, the direction of the center portion of the bridge is in a first crystalline direction (i.e., 100) of the substrate 230.

As mentioned above, the center portion 220 of the suspended bridge can buckle away from the substrate 230 after releasing the film (i.e., center portion 220 of the superconducting metal line 222) with an anisotropic etch. The reason that buckling is salient is because there is a threshold gap 240 (e.g., clearance between the superconducting metal line 222 and the substrate 230) that provides a more reliable fuse and/or anti-fuse. For example, the suspended bridge 220 having this sufficient gap can receive the output power of a laser to create an electrical open between a left portion and a right portion of the superconducting metal line 220.

This buckling can be caused to occur in different ways. In one embodiment, the buckling is ensured by providing a metal film with overall compressive stress with stress gradient across the thickness of the film 222. Alternatively, or in addition, the buckling is ensured by creating a bimorph structure by placing a second material directly on top or directly below the center portion of the first metal, wherein the second material has a coefficient of expansion that is different from that of the first metal line 222. The second material (not shown in FIG. 2) can then be removed via any suitable technique (e.g., wet or dry etching, ion milling, etc.). This second material can locally impart a compressive stress and a stress gradient to the superconducting metal line 222 above or below it.

In one embodiment, etch release holes 202 are provided in the center portion of the metal line 222. In this regard, the top view 200 illustrates etch release holes 202 between a left portion 204 and a right portion 206 of the suspended bridge 220. Stated differently, the substrate 230 can be etched through the etch release holes 202, which facilitates the popping (relieving the stress of the metal line by buckling away from the surface of the substrate 230) of the suspended bridge 220.

While a regular pattern of rectangular release holes 202 are depicted in FIG. 2, any shape or pattern is supported by the teachings herein, based on the release characteristics. In one embodiment, the etch release holes 202 are non-uniform in geometry. For example, the etch release holes 202 that are further away from the center of the metal line 222 are smaller than those closer to the center. In one example, there is a gradual tapering (i.e., increase) in hole size towards the center of the etch release holes between the left portion 204 and the right portion 206.

The center portion 220 of the superconducting metal line 222 functions as a suspended bridge having a cavity 240 between the center portion 220 and the substrate 230. The center portion 220 is configured to receive an output of the laser to provide an electrical open between the left portion 204 and the right portion. By virtue of the process described in the context of FIG. 2, an undercut of the substrate can be limited to the etch release holes 202 region. In this way, the same wafer can be used for further processing and development of additional semiconductor structures thereon, including additional anti-fuses, and transistor structures. In one embodiment, anti-fuses and fuses can share a same superconducting metal plane, where fuses can be aligned along the 100 crystalline direction of silicon substrate, whereas anti-fuses can be aligned along the 110 crystalline direction of the substrate.

Although the figures generally illustrate structures that are consistent with fuses by way of example for reasons of simplicity, anti-fuses are within the scope of the present disclosure. In one embodiment, anti-fuses that can be on the same superconducting metal plane as that of the fuse. For example, both anti-fuses and fuses can be fabricated at the same time and having a common superconducting metal layer and can even be programmed concurrently.

While the manufacture of a single superconducting switch device or a pair of switch devices is described for the purposes of discussion, it will be understood that other configurations, as well as those having multiple fuses and anti-fuses that disconnect or connect multiple superconducting circuit elements are supported by the teachings herein.

In one aspect, the method and structures as described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### Example Processes

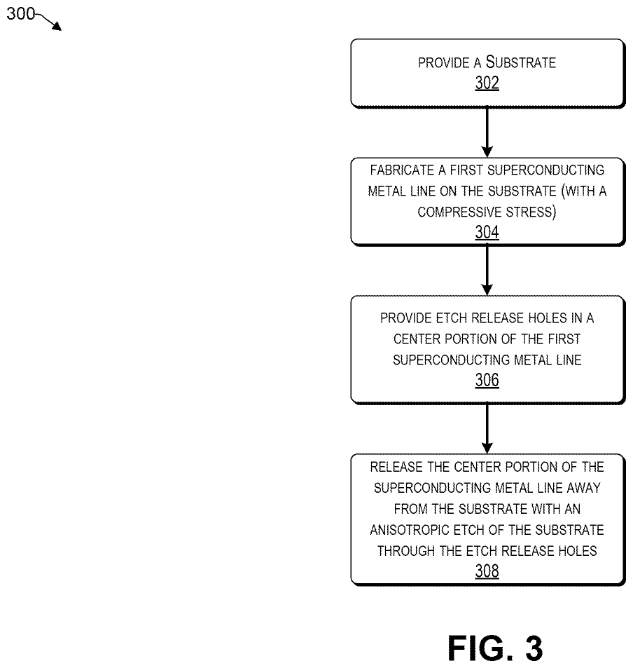

With the foregoing overview of the descriptions of superconducting switch devices, it may be helpful now to consider a high-level discussion of example fabrication processes of the structures discussed herein that may be controlled by an appropriately configured one or more computing devices. To that end, FIG. 3 presents an example processes 300 for constructing superconducting switch devices, consistent with illustrative embodiments. More specifically, process 300 relates to methods of constructing superconducting switches that may be implemented as fuses and/or anti-fuses. Process 300 is illustrated as a collection of blocks in a logical flowchart, which represents sequence of operations that can be implemented in hardware.

FIG. 3 is a process 300 that relates to orchestration of the creation of superconducting switch device that includes a shallow anisotropic etch that uses the substrate as a sacrificial material, similar to that discussed in the context of FIG. 2. At block 302, a substrate is provided. At block 304, a first superconducting metal line is deposited over the substrate. The superconducting metal line has a left portion, a right portion, and a center portion patterned along a first crystalline direction of the substrate. At block 308, etch release holes are provided in the center portion of the first superconducting metal line. At block 308, the center portion of the superconducting metal line is buckled away from the substrate with an anisotropic etch through the etch release holes.

### Example Computer Platform

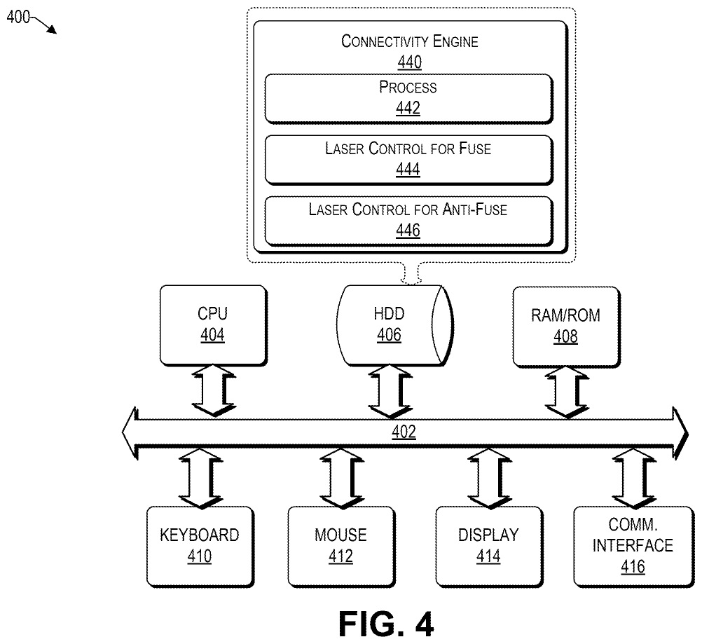

As discussed above, functions relating to methods and systems for providing superconducting switch devices can use one or more computing devices connected for data communication via wireless or wired communication. FIG. 4 is a functional block diagram illustration of a computer hardware platform that can be used to control various aspects of a suitable computing environment 400 in which the various embodiments of the features discussed herein can be implemented. While a single computing device is illustrated for simplicity, it will be understood that a combination of additional computing devices, program modules, and/or combination of hardware and software can be used as well. The computer platform 400 may include a central processing unit (CPU) 404, a hard disk drive (HDD) 406, random access memory (RAM) and/or read only memory (ROM) 408, a keyboard 410, a mouse 412, a display 414, and a communication interface 416, which are connected to a system bus 402.

In one embodiment, the HDD 406, has capabilities that include storing a program that can execute various processes, such as the connectivity engine 440, in a manner described herein. The connectivity engine 440 may have various modules configured to perform different functions. For example, there may be a process module configured to control the different manufacturing processes discussed herein and others. There may be a laser control module 444 operative to provide an appropriate energy output and duration for controlling a state of a fuse. In some embodiments, the same laser control module 444 can also control anti-fuses. Alternatively, there can be a separate laser control module 446 operative to provide an appropriate energy output and duration for controlling a state of an anti-fuse.

### CONCLUSION

The descriptions of the various embodiments of the present teachings have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

The components, steps, features, objects, benefits and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed is:

1. A method of constructing a superconducting switch, comprising:
providing a substrate;
fabricating a first superconducting metal line over the substrate, wherein the superconducting metal line is patterned along a first crystalline direction of the substrate;
providing one or more etch release holes in a center portion of the first superconducting metal line; and
releasing the center portion of the superconducting metal line from the substrate with an anisotropic etch through the etch release holes.

2. The method of claim 1, wherein the first crystalline direction of the substrate is 100.

3. The method of claim 2, wherein the anisotropic etch through the etch release holes is 300 nm or less.

4. The method of claim 1, wherein the anisotropic etch is by way of wet etch using at least one of Potassium Hydroxide (KOH), all quaternary hydroxides like tetramethyl ammonium hydroxide (TMAH), or tetraethyl ammonium hydroxide (TEAH).

5. The method of claim 1, wherein the first superconducting metal line is fabricated with a compressive stress during the deposition such that the center portion of the superconducting metal line buckles away from the substrate upon release.

6. The method of claim 1, wherein:
a second material is placed directly on top or directly below the center portion of the first superconducting metal line creating a bimorph structure that facilitates buckling of the center portion of the superconducting metal line away from the substrate upon release; and
the second material has a coefficient of expansion that is different from that of the first superconducting metal line.

7. The method of claim 6, further comprising removing the second material upon buckling of the center portion of the first superconducting metal line.

8. The method of claim 1, wherein the etch release holes are rectangular and are arranged in a staggered pattern with rows of holes offset from each other such that there is an etch path across a width of the superconducting metal line.

9. The method of claim 1, wherein the etch release holes have different sizes and shapes optimized to provide for releasing the center portion of the superconducting metal line while minimizing an amount and/or a distance of undercut elsewhere on the substrate.

10. The method of claim 1, wherein the released center portion of the first superconducting metal line is a fuse that is configured to receive an output of a laser.

11. The method of claim 1, wherein the released center portion of the first superconducting metal line is an anti-fuse that is configured to receive an output of a laser.

12. The method of claim 11, further comprising providing a fuse on same metal plane of the first superconducting metal line.

13. The method of claim 1, wherein:
the fuse is aligned along a 100 crystalline direction of silicon substrate; and
the anti-fuse is aligned along a 110 crystalline direction of the substrate.

14. The method of claim 1, wherein:
the substrate comprises silicon (Si); and
etching a portion of the substrate comprises using at least one of tetramethyl ammonium hydroxide (TMAH), potassium hydroxide (KOH), or tetraethyl ammonium hydroxide (TEAH).

15. A fuse structure comprising:
a substrate;
a first superconducting metal line on top of the substrate, wherein the superconducting metal line has a lateral first portion, a second lateral portion, and a lateral center portion between the lateral first and second portions, patterned along a first crystalline direction of the substrate; and
one or more etch release holes in the center portion of the first superconducting metal line, wherein the center portion of the superconducting metal line has a gap from the substrate based on the etch release holes.

16. The fuse structure of claim 15, wherein the first crystalline direction of the substrate is 100.

17. The fuse structure of claim 15, wherein the first superconducting metal line includes a compressive stress configured to buckle the center portion of the first superconducting metal line away from the substrate.

18. The fuse structure of claim 15, further comprising:
a second material on top or directly below the center portion of the first superconducting metal line creating a bimorph structure that facilitates buckling of the released portion of the superconducting metal line away from the substrate upon release, wherein the second material has a coefficient of expansion that is different from that of the first superconducting metal line.

19. The fuse structure of claim 15, wherein the center portion of the superconducting metal line has a gap between the center portion and the substrate that is sufficient to receive an output power of a laser to create an electrical open between the lateral first portion and the lateral second portion of the superconducting metal line.

20. The fuse structure of claim 15, wherein the center portion of the superconducting metal line has a gap between the center portion and the substrate that is sufficient to receive an output power of a laser to create an electrical short between the lateral first portion and the lateral second portion of the superconducting metal line.

21. The fuse structure of claim 15, wherein the etch release holes are rectangular and arranged interstitially between rows of release holes.
